(19) United States
(12) Patent Application Publication
(10) Pub. No.: US 2026/0223632 A1
(43) Pub. Date: Jul. 30, 2026

(54) BIAXIAL OPTICAL SENSOR SYSTEM

(71) Applicant: Lam Research Corporation, Fremont, CA (US)

(72) Inventors: Jason Gordon Galginaitis, Portland, OR (US); Jacob Lee Hiester, Newberg, OR (US)

(21) Appl. No.: 19/152,363

(22) PCT Filed: Feb. 2, 2024
(86) PCT No.: PCT/US2024/014359

§ 371 Date: Jul. 30, 2025

Related U.S. Application Data
(60) Provisional application No. 63/483,499, filed on Feb. 6, 2023.

(51) Int. Cl. H10P 72/50; G01B 11/27

(52) U.S. Cl. CPC H10P 72/53; G01B 11/27

(57) ABSTRACT

This disclosure pertains to biaxial optical sensor systems that may be used to evaluate variations in thickness and/or elevational changes about the circumference of an object, e.g., a semiconductor wafer, as the object is rotated about a rotational axis. Such sensor systems may feature a pair of light sources and corresponding light detectors. Each light source may be configured to direct light along a corresponding direction and towards the corresponding light detector; the directions along which the light is directed may be at oblique or right angles to each other and at oblique angles to axes parallel to the rotational axis.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

During semiconductor wafer processing, semiconductor wafers are often subjected to one or more processes that may cause material to be deposited on or etched from such semiconductor wafers. It is often the case that it is desirable to ensure that such semiconductor wafers are properly oriented and centered relative to various pieces of equipment used to handle the semiconductor wafer and/or support the semiconductor wafer during such processing.

In some instances, a semiconductor processing tool may be equipped with a wafer aligner that may be used to rotate a semiconductor wafer in order to change the semiconductor wafer's absolute orientation, e.g., in preparation for loading the semiconductor wafer onto a wafer handling robot in a particular orientation so as to allow later placement of the semiconductor wafer in a desired orientation relative to a pedestal or other wafer-supporting device. Such wafer aligners may also be configured, in some cases, to allow the wafer to also be centered on a particular point.

Wafer aligners such as those described above may have a wafer support that may be caused to rotate about a rotational axis while supporting the semiconductor wafer. Such wafer aligners may be equipped with a curtain beam sensor that is oriented so as to direct a planar light beam along a direction that is parallel to, and co-planar with, the rotational axis such that the edge of the semiconductor wafer intersects the planar light beam. As the semiconductor wafer is rotated, the curtain beam sensor is able to track variation in the position of the edge of the semiconductor wafer relative to the rotational axis. This allows, for example, the location of an indexing notch on the perimeter of the semiconductor wafer to be identified and for a determination to be made as to how centered the wafer is relative to the rotational axis.

Such wafer aligners, however, are limited in their data collection capabilities, and only able to collect information such as that discussed above.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a support structure, a first light source supported by the support structure and configured to emit first light along a first direction that is at an oblique angle to a first reference axis that is parallel to a vertical axis associated with the support structure, and a second light source supported by the support structure and configured to emit second light along a second direction that is at an oblique or perpendicular angle to the first direction and that is at an oblique angle to a second reference axis that is parallel to the vertical axis. The apparatus may further include a first light detector supported by the support structure and configured so as to detect the first light emitted by the first light source and a second light detector supported by the support structure and configured so as to detect the second light emitted by the second light source.

In some implementations, the first direction may be orthogonal to the second direction.

In some implementations, the first direction may be at a 45° angle to the first reference axis.

In some implementations, the first direction may be at an oblique angle to the second direction.

In some implementations, the first light may be a first collimated planar beam of light that is coplanar with the first reference axis, and the second light may be a second collimated planar beam of light that is coplanar with the second reference axis.

In some implementations, the vertical axis may be coplanar with the first collimated planar beam of light and the second collimated planar beam of light.

In some implementations, the first light source may include a first linear array of first light-emitting devices arranged along a first array axis and the second light source may include a second linear array of second light-emitting devices arranged along a second array axis. The first array axis may be perpendicular to the first direction and the second array axis may be perpendicular to the second direction.

In some implementations, the first array axis and the second array axis may each lie in planes that are parallel to or coplanar with one another.

In some implementations, the first light detector may include a first linear charge-coupled device (L-CCD) having a corresponding first photo-sensitive surface that is orthogonal to the first direction, and the second light detector may include a second L-CCD having a corresponding second photo-sensitive surface that is orthogonal to the second direction.

In some implementations, the first light source and the second light source may both be positioned so as to direct a portion of the first light and a portion of the second light, respectively, through a first point.

In some implementations, the support structure may not extend into a region that has a center axis that is coaxial with or parallel to the vertical axis, and the center axis may extend into a space between the first light source and the first light detector and into another space between the second light source and the second light detector.

In some implementations, the apparatus may further include a wafer support that is configured to rotate about a rotational axis.

In some implementations, the apparatus may further include a controller that is configured to: a) obtain measurements in a first frame of reference that is not aligned with the vertical axis using the first light source, the second light source, the first light detector, and the second light detector, each measurement indicating an amount of the first light and the second light emitted by the first light source and the second light source, respectively, that is detected by the first light detector and the second light detector, respectively, b) determine a position of an object in the first frame of reference based on the measurements, and c) convert the position of the object in the first frame of reference into an equivalent position in a second frame of reference, wherein the second frame of reference has a first axis that is parallel to the vertical axis and a second axis that is perpendicular to the first axis.

In some implementations, the controller may be further configured to d) cause the rotatable wafer support to rotate about the rotational axis and through a plurality of different rotational positions for a first set of measurements associated with the object and e) repeat (a) through (c) for each rotational position.

In some implementations, the controller may be configured to, as part of (d), cause the rotatable wafer support to move through N rotational positions and to rotate by the same amount when rotating between each set of adjacent rotational positions, and to, also as part of (d), rotate at least 360° minus 360°/N.

In some implementations, the controller may be further configured to determine a maximum displacement of the position along the first axis across the plurality of different rotational positions indicated by the first set of measurements for the object.

In some implementations, the controller may be further configured to determine a maximum displacement of the position along the second axis across the plurality of different rotational positions indicated by the first set of measurements for the object.

In some implementations, the object may be a semiconductor wafer.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an example apparatus having a biaxial optical sensor system for simultaneously evaluating off-centeredness of a semiconductor wafer from a rotational axis as well as elevational change along a wafer edge thereof.

FIG. 2 depicts a support structure and attached first light source, second light source, first light detector, and second light detector without a wafer support.

FIG. 3 depicts the apparatus of FIG. 1 with a semiconductor wafer loaded into it.

FIGS. 4 and 5 depict the apparatus of FIG. 3 with annotations relating to coordinates in first and second frames of reference.

FIG. 6 depicts an example apparatus with a biaxial optical sensor system in which the axes of measurement are not orthogonal.

FIG. 7 depicts another example apparatus with a biaxial optical sensor system in which the axes of measurement are not orthogonal.

FIG. 8 depicts FIG. 6, but with additional annotations added.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As noted above, semiconductor processing tools may be configured to deposit material on, or etch material off of, semiconductor wafers. As a result of such processing, the semiconductor wafers being processed may experience changes in thickness, e.g., along the edge of the semiconductor wafer. A further result of such processing may be, in some cases, that the semiconductor wafer experiences warping or bending, resulting in the edge of the semiconductor wafer no longer being planar, i.e., no longer having all points along the edge of the wafer able to lie along a common plane. For example, a circular wafer may bend in a first direction about a first axis that is perpendicular to the wafer center axis, thereby taking on a shape having a parabolic or curved cross-section in a plane perpendicular to the first axis. In another example, a circular wafer may bend in the first direction as described above, but also in a second direction about a second axis that is orthogonal to the wafer center axis and the first axis, thereby resulting in the wafer having a more complex, saddle-like shape. In either case, the edge of the wafer is no longer planar since it is not possible to define a plane on which all of the points along the edge of the wafer lie. In such cases, the edge of the semiconductor wafer may oscillate up and down as the wafer is rotated about a rotational axis (e.g., its nominal center axis) and the edge passes through a plane that is parallel to, and coplanar with, the rotational axis. Such changes in elevation of the wafer edge are not able to be detected by conventional wafer aligners, as such aligners are only capable of detecting lateral/horizontal changes in the position of the wafer edge.

However, a new type of wafer aligner that uses a pair of light sources and corresponding light detectors configured in a particular way is capable of not only measuring lateral movements of the wafer edge during rotation of the semiconductor, but also vertical movements of the wafer edge during such rotation. Each light source may be configured to direct light along a corresponding direction and towards the corresponding light detector; the directions along which the light is directed may be at oblique or right angles to each other and at oblique angles to axes parallel to the rotational axis. An oblique angle, it will be understood, is an angle that is not 0° and not a multiple of 90°, i.e., a non-parallel and non-perpendicular angle. Such a configuration allows for evaluation of the movement of the wafer edge as the semiconductor wafer is rotated about a rotational axis. This allows the warpage of the semiconductor wafer to be characterized.

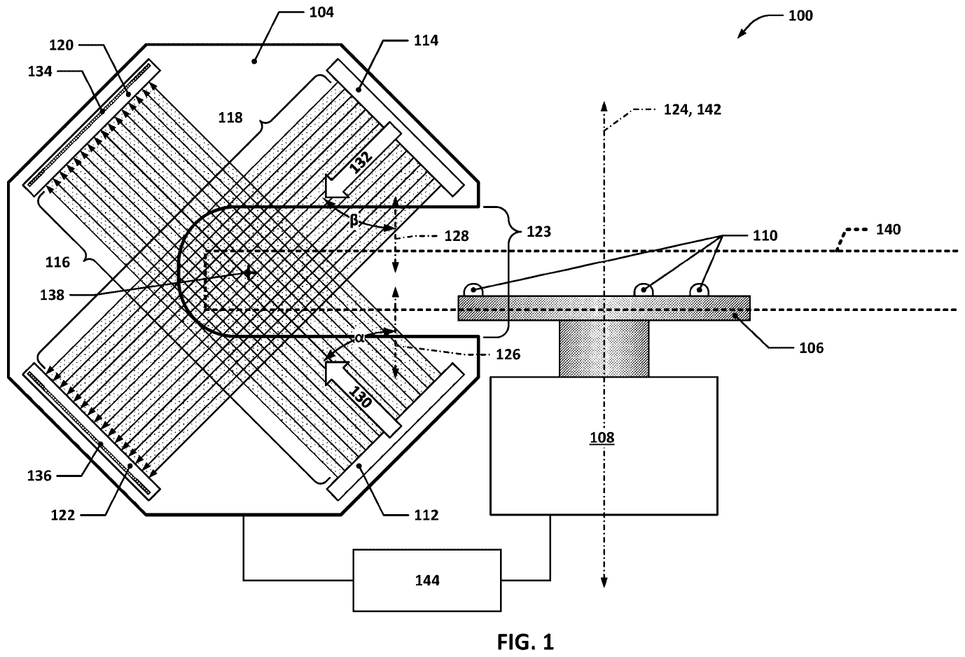

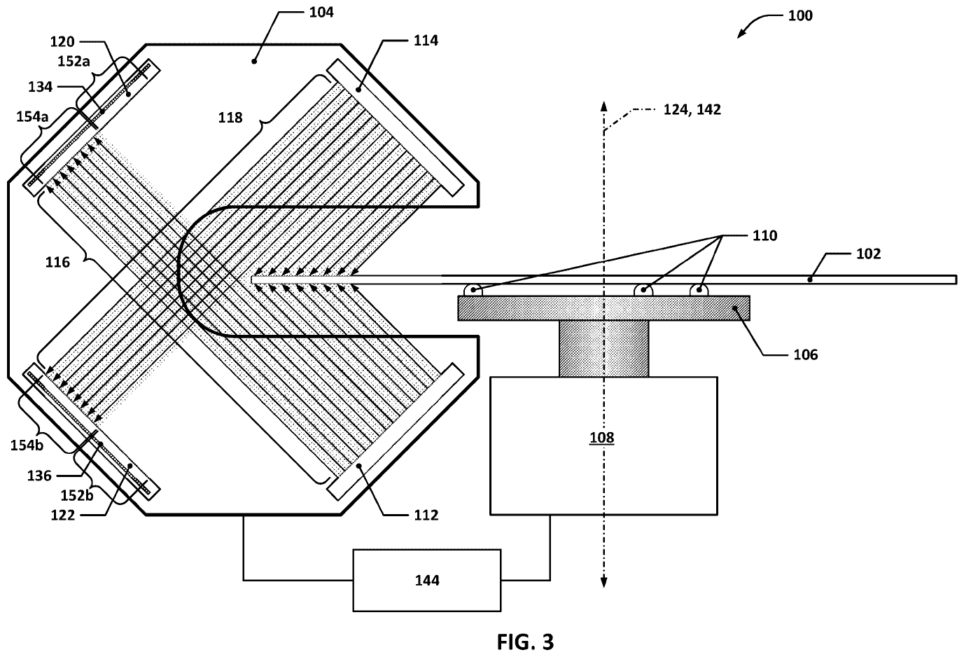

FIG. 1 depicts an apparatus 100 that includes a wafer support 106 that may be connected with a drive motor 108 that may be configured to rotate the wafer support 106 about a rotational axis 124. The wafer support 106 may have a plurality of low-contact area (LCA) features 110, e.g., three LCA features 110, that may be configured to support a semiconductor wafer (see FIG. 3) that is placed on the wafer support 106 for measurement operations using the apparatus. The LCA features 110 may, for example, have domed or rounded tops, or very small circular planar top surfaces, that may minimally contact the underside of the semiconductor wafer.

As can be seen from FIG. 1, the apparatus 100 may further include a support structure 104. The support structure 104 may support a first light source 112 and a second light source 114, as well as a first light detector 120 and a second light detector 122. The first light source 112 may be configured to direct first light 116 along a first direction 130 such that the first light 116 is detectable by the first light detector 120, while the second light source 114 may be configured to direct second light 118 along a second direction 132 such that the second light 118 is detectable by the second light detector 122.

The first light source 112 and the second light source 114 may both be configured, in at least some implementations, to emit at least partially collimated beams of light that, when unobstructed, strike the first light detector 120 and the second light detector 122, respectively, across generally linear areas on the first light detector 120 and the second light detector 122, respectively, that are photosensitive. It will be understood, of course, that such collimation may, in some cases, result in a light beam that is collimated with respect to the light rays that are co-planar with a particular plane, e.g., a plane that is coplanar with an axis along which a light detector is configured to measure or detect light. In such examples, at least some of the light rays in the beam that are not co-planar with that plane may fan out in a non-collimated fashion such that they do not strike the light detector. However, in other implementations, the light beams may be more fully collimated, e.g., into planar light beams (which may commonly be referred to as “light curtains”). For clarity, when a plane or similar element is described as being coplanar with a line, this is to be understood as meaning that the line lies on the plane or similar element, e.g., is parallel to and coincident with the plane or similar element.

For example, the first light source 112 and the second light source 114 may both be provided using linear arrays of light-emitting devices, e.g., the first light source 112 may be provided using a first linear array of first light-emitting devices arranged along a first array axis, while the second light source 114 may be provided using a second linear array of second light-emitting devices arranged along a second array axis. The light-emitting devices may, for example, be laser diodes, light-emitting diodes coupled with collimating devices, e.g., lenses, etc. In some such implementations, the first array axis may be perpendicular to the first direction and the second array axis may be perpendicular to the second direction. In some further such implementations, the first array axis and the second array axis may each lie in planes that are parallel to or coplanar with one another.

Similarly, the first light detector 120 and the second light detector 122 may have a first linear charge-coupled device (L-CCD) and a second L-CCD, respectively, that have long axes that are oriented so as to be perpendicular to reference planes that are at oblique or perpendicular angles to one another. An L-CCD may, for example, include a linear array of sensor pixels, each of which is capable of detecting when light is incident thereupon. In other implementations, other types of linearly-arranged light-detecting sensors may be used, e.g., linear arrays of photodiodes, linear arrays of photoresistors, single photodiodes that have surface areas sufficient to receive the light emitted by the light source, etc. It will be appreciated that any light-detecting sensor may be used in the first light detector 120 and the second light detector 122 as long as the light-detecting sensor is able to provide a sufficiently accurate indication of how much of occlusion occurs of light that is incident on the light-detecting sensor along a linear path, thereby allowing for a determination to be made as to the location of the edge of an object that is causing the occlusion relative to the light-detecting sensor. Such arrangements of light sources and light detectors may sometimes be referred to as light curtain sensors or light curtain measurement sensors. Such sensors may generally be designed to detect the position of an edge of an object that intersects with a sensing plane of the sensor; such positions may be detected as either a location or as a percentage of total dynamic range of the sensor (which may then be converted to a location). For example, if such a sensor has a sensing area that is 2.1″ in length and the sensor generates a signal indicating that 34% of the sensing area is not receiving light, such data may be interpreted by a controller as indicating that the edge of an object is located at 0.714″ from the end of the sensing area that is “dark.” Generally speaking, the light that is directed at the light detector in such a sensor may be collimated and directed toward the light detector along directions that are parallel and perpendicular to the sensing area of the light detector in order to reduce the potential of light being able to cross underneath the object causing the occlusion of the light detector and be incident on portions of the light detector that should be occluded.

As mentioned earlier, conventional wafer aligners may use a similar type of light source and light detector, but arrange them such that the light emitted by the light source travels along directions that are parallel to the rotational axis of the wafer support of the wafer aligner, thereby allowing for accurate measurement of horizontal movement of the edge of a semiconductor wafer being evaluated using the aligner. Such arrangements, however, provide no ability to evaluate the vertical position of the edge of the wafer being evaluated using the aligner.

The present apparatus 100, however, orients the first light source 112 and the second light source 114 such that the first direction 130 is at an oblique angle relative to a first reference axis 126 that is parallel to the rotational axis 124 and such that the second direction 132 is also at an oblique angle relative to a second reference axis 128 that is also parallel to the rotational axis 124. The first direction 130 and the second direction 132 are, in some implementations, perpendicular or orthogonal to one another but may alternatively be at an oblique angle to one another in other implementations. In some implementations, such as that shown in FIG. 1, the first direction 130 and the second direction 132 may be orthogonal to one another, and the first direction 130 and the second direction 132 may both be at 45° angles to the first reference axis 126 and the second reference axis 128, respectively.

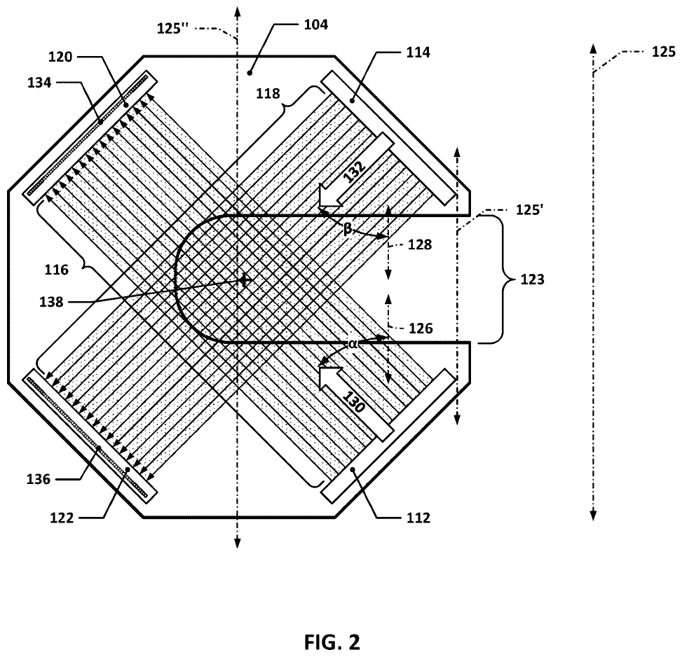

It will be understood that the elements in FIG. 1 may also be provided separately, e.g., the support structure 104 and attached first light source 112, second light source 114, first light detector 120, and second light detector 122 may be provided separately from the wafer support 106 and associated drive motor 108, e.g., the support structure 104 and attached first light source 112, second light source 114, first light detector 120, and second light detector 122 may be provided as an add-on unit that may be installed in a conventional wafer aligner (either supplementing the sensor used in the wafer aligner or replacing it) to provide enhanced measurement capability, e.g., both radial and elevational measurement capability, in the wafer aligner. In recognition of this, it will be understood that features that are discussed herein as being defined relative to the rotational axis 124 of the wafer support 106 may also, in some implementations, be defined relative to a vertical axis associated with the support structure 104 that is, or would be, coaxial with or parallel to the rotational axis 124 when the support structure 104 and attached hardware is installed in an apparatus having the wafer support 106 in the configuration and orientation in which the support structure 104 and attached hardware are intended to be used. Thus, references to the rotational axis 124 herein may also be understood to be references to the vertical axis. For example, FIG. 2 depicts the support structure 104 and attached first light source 112, second light source 114, first light detector 120, and second light detector 122 without the wafer support 106 and drive motor 108 present. Also shown is a vertical axis 125, which may be coaxial with, or at least parallel to, the rotational axis 124 of the wafer support 106 when the support structure is integrated with the wafer support 106 and drive motor. It will be appreciated that the support structure 104 and attached first light source 112, second light source 114, first light detector 120, and second light detector 122 may also potentially be implemented in devices that do not feature a wafer support 106 that is configured to rotate about a rotational axis 124; in such devices, the vertical axis 125 associated with the support structure may not be aligned with a rotational axis 124.

The support structure 104 may also be configured to support the first light source 112, the second light source 114, the first light detector 120, and the second light detector 122 such that a portion of the first light 116 and a portion of the second light 118 both pass through a first point 138. Put another way, the first light source 112, the second light source 114, the first light detector 120, and the second light detector 122 may be arranged such that the first point 138 is between the first light source 112 and the first light detector 120 and is also between the second light source 114 and the second light detector 122. In practice, the first point 138 may actually be a region or volume of space, e.g., in FIG. 1, the square-shaped region (tilted at 45° from horizontal) in which the arrows representing the first light 116 overlap with the arrows representing the second light 118.

The support structure may have any suitable shape that is sufficient to support the first light source 112, the second light source 114, the first light detector 120, and the second light detector at the locations necessary to achieve, for example, the arrangements of such components discussed above. However, the support structure will generally not extend into at least a cylindrical region 140 that has a center axis 142 that is coaxial with the rotational axis 124 and that extends at least into a space between the first light source 112 and the first light detector 120 as well as into a space between the second light source 114 and the second light detector 122.

For example, in FIG. 1, the support structure 104 is C-shaped, with the first light source 112 and the second light source 114 located at the tips of the “C” and the first light detector 120 and the second light detector 122 located along the arc of the “C” opposite the ends of the “C.” The opening 123 between the ends of the “C,” as well as the interior of the “C,” are free of material in the depicted support structure 104, thereby allowing the arms of the “C” to extend over and under, for example, a semiconductor wafer 102 (see FIG. 3) that may be supported by the wafer support 106. Such an arrangement may, for example, allow such a semiconductor wafer 102 to extend into the region or volume where the first light 116 and the second light 118 intersect or overlap (when viewed along an axis that is perpendicular to the first direction 130 and the second direction 132).

Returning to FIG. 2, the vertical axis 125 may, for example, be a vertical axis 125′ that is a vertical axis of the opening 123 defined by the support structure 104. For example, the opening 123 defined by the support structure 104 may be configured so as to extend in a transverse direction, e.g., a direction that is perpendicular to the nominal plane of the semiconductor wafer, that is, for example, parallel to the vertical axis of the apparatus in which the support structure is installed or to be installed. The vertical axis 125 may also or alternatively be a vertical axis 125″ that is overlapped by, or overlaps, the first light 116 and the second light 118 when viewed along a direction that is perpendicular to the first direction 130 and the second direction 132 and that is interposed between at least a portion (or in some cases, all) of the first light source 112 and at least a portion (or in some cases, all) of the first light detector 120 and between at least a portion (or in some cases, all) of the second light source 114 and at least a portion (or in some cases, all) of the second light detector 122. Such a vertical axis 125″ may also be in a plane that is parallel to a plane generally defined by the first direction 130 and the second direction 132.

FIG. 3 depicts the apparatus of FIG. 1 with a semiconductor wafer loaded therein. As can be seen, a semiconductor wafer 102 has been placed on the wafer support 106 of the apparatus 100. The semiconductor wafer 102 may be placed on the LCA features 110 of the wafer support 106 such that the semiconductor wafer 102 is centered, or generally centered, on the rotational axis 124 of the wafer support 106. Such placement may, for example, be performed by a wafer-handling robot or other system that is configured to transport semiconductor wafers from location to location within a semiconductor processing tool.

As can be seen, the semiconductor wafer 102 may extend into the region through which the first light 116 and the second light 118 travel, such that portions of the first light 116 and the second light 118 are obstructed by the semiconductor wafer 102, thereby causing the amounts of the first light 116 and the second light 118 that reach the first light detector 120 and the second light detector 122, respectively, to be decreased. For example, in FIG. 3, the portion of the first light 116 that is not blocked by the semiconductor wafer 102 is incident on an unobstructed portion 154a of the first light detector 120, while the portion of the first light 116 that is blocked by the semiconductor wafer 102 is prevented by the semiconductor wafer 102 from reaching an obstructed or occluded portion 152a of the first light detector 120. Similarly, the portion of the second light 118 that is not blocked by the semiconductor wafer 102 is incident on an unobstructed portion 154b of the second light detector 122, while the portion of the second light 118 that is blocked by the semiconductor wafer 102 is prevented by the semiconductor wafer 102 from reaching an obstructed or occluded portion 152b of the second light detector 122. Accordingly, the signals received by a controller 144 from the first light detector 120 and the second light detector 122 will indicate the extent to which the first light detector 120 and the second light detector 122 are obstructed, thereby providing data that allows a determination to be made as to the location of the edge of the semiconductor wafer 102 that is causing the obstruction relative to the support structure 104 and/or the rotational axis 124. The controller 144 is shown as being connected with the support structure 104, but it will be understood that this represents a connection between the controller 144 and the various electronic elements supported by the support structure 104, e.g., the first light source 112, the second light source 114, the first light detector 120, and the second light detector 122. In some implementation, the first light source 112 and the second light source 114 may not be connected to the controller at all, e.g., may be arranged to be “always on” when power is provided to the apparatus 100, or be provided power when the drive motor 108 is provided power.

Generally speaking, when evaluating dimensional characteristics of semiconductor wafers such as the semiconductor wafer 102, it is desirable to define such characteristics relative to a frame of reference that is aligned with the plane and center axis of the semiconductor wafer. For example, the semiconductor wafer 102 is generally in the form of a large, flat, circular disk. The circular faces of the semiconductor wafer generally define a plane, e.g., a mid-plane midway between the two circular faces, and a center axis, e.g., an axis that passes through the center(s) of the circular face(s) and is perpendicular to the plane. Of course, if there is wafer warpage or bowing, the circular surfaces may not be planar, but they will still be understood to be nominally planar and to define a center axis. When the semiconductor wafer 102 is placed on the aligner and evaluated, the characteristics of interest may, for example, include the horizontal/radial deviation between the center axis of the semiconductor wafer 102 and the rotational axis 124 of the wafer support 106. Such characteristics may also include the amount by which the distance between a reference plane that is orthogonal or perpendicular to the rotational axis 124 and the edge of the semiconductor wafer 102 varies around the circumference of the semiconductor wafer 102. In the arrangement shown in FIG. 1, the light source/detector pairs (the first light source 112 and the first light detector 120, as well as the second light source 114 and the second light detector 122) are arranged such that neither light source/detector pair is able to collect data that is, in isolation, determinative of either of the characteristics discussed above. However, combining the data from both light source/detector pairs allows both characteristics discussed above to be meaningfully evaluated.

Moreover, the systems disclosed herein allow for both characteristics of the semiconductor wafer 102 to be evaluated without regard for issues such as wafer transparency, surface finish, reflectivity, etc. For example, one potential solution that could be used to evaluate changes in elevation in the edge of a semiconductor wafer would be to utilize a downward-looking, light-based reflectance sensors, e.g., sensors that direct an optical beam at a surface and then, based on reflected characteristics of such a beam, determine how far away the surface is. However, such sensors are often unreliable when used to determine how far away a highly reflective surface, e.g., such as may be found on a semiconductor wafer, is. Systems such as are disclosed herein may provide an inexpensive and easily integrated option for evaluating such characteristics. For example, the systems disclosed herein may be implemented using the same type of light source/light detector sensors that are used in conventional wafer aligners. Moreover, the support structure 104 may have a similar shape and geometry to support structures used in such conventional aligners. Thus, the apparatuses discussed herein may be easily integrated into existing systems having conventional wafer aligners by simply replacing the conventional aligner with an apparatus as disclosed herein.

Key to the operation of the apparatuses discussed herein is the fact that the light source/detector pairs are specifically arranged so as to have measurement axes, e.g., axes that are generally perpendicular to the first direction 130 or the second direction 132, respectively, that are arranged so as to not be parallel to or perpendicular to the rotational axis 124 of the wafer support 106 (and are thus not parallel or perpendicular to a first axis or a second axis of a frame of reference that are parallel to or perpendicular to, respectively, the rotational axis 124).

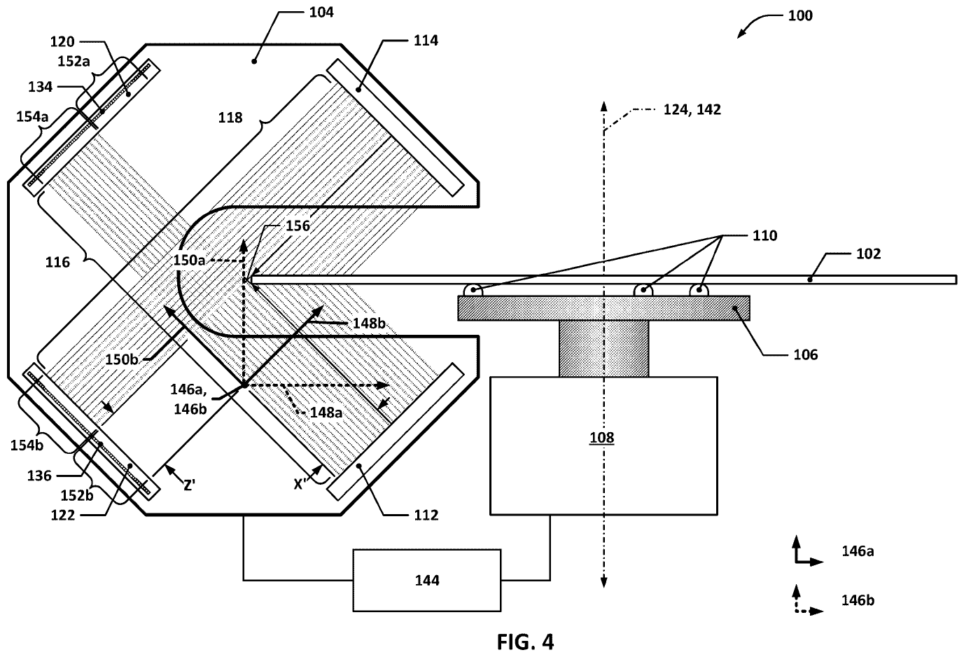

FIGS. 4 and 5 are similar to FIG. 3, but with frames of reference added. In FIG. 4, a first frame of reference 146a and a second frame of reference 146b are shown. The first frame of reference 146a in FIG. 4 is shown in dotted lines and has a first axis 148a that is perpendicular to the rotational axis 124 and a second axis 150a that is perpendicular to the first axis 148a (and parallel to the rotational axis 124). The first frame of reference 146a is, for example, a frame of reference in which the characteristics discussed above (off-centeredness of the center axis of the semiconductor wafer 102 relative to the rotational axis 124 and the vertical displacement of the edge of the semiconductor wafer 102 about its perimeter) may need to be evaluated. It will be understood that the labels of “first” and “second” used here in the specification may be reversed, depending on the context of a particular discussion or claim.

The second frame of reference 146b is shown in solid lines and is, for illustration purposes, shown as having an origin that is the same as the first frame of reference 146a. It will be understood, of course, that the first frame of reference 146a and the second frame of reference 146b may have different origins. The second frame of reference 146b has a first axis 148b that is perpendicular to a second axis 150b of the second frame of reference 146b. The two frames of reference 146a/b may, for example, both be in the same plane. However, as can be seen, the first axis 148b of the second frame of reference 146b may be at an angle θ from the first axis 148a of the first frame of reference 146a. The angle θ may be, as shown in FIG. 4, 45°, but may also be set to other oblique angles, depending on the orientation of the first light detector 120 and/or the second light detector 122.

The data received from the first light detector 120 and the second light detector 122 regarding the amount of occlusion that the first light detector 120 and the second light detector 122 experience may be used to determine the location of an intersection 156 of two lines or planes. Each such line or plane is colinear or coplanar with the transition between obstructed light rays and unobstructed light rays from one of the first light source 112 or the second light source 114. Thus, for example, if the first light detector 120 and the second light detector 122 are arranged so as to have light-sensing surfaces that are orthogonal to one another, as shown in FIGS. 1 and 3, the light-sensing surfaces thereof may represent orthogonal coordinate axes that may define the second frame of reference 146b. The signals indicating the amount of occlusion of the first light detector 120 and the second light detector 122 may, in such an example, represent the locations along the first axis 148b of the second frame of reference 146b and the second axis 150b of the second frame of reference 146b, respectively, where such lines or planes cross those axes. In other words, the coordinates in the second frame of reference 146b where such lines or planes intersect with one another.

It will be understood that since the first light 116 is striking the bottom of the semiconductor wafer 102 and the second light 118 is striking the top of the semiconductor wafer 102, the distance between the top and bottom surfaces of the semiconductor wafer 102 may cause the actual intersection 156 between the lines or planes representing the transitions between the occluded and un-occluded first light 116 and second light 118 to be located somewhat radially outward of the edge of the semiconductor wafer 102 and generally midway between the top and bottom surface of the semiconductor wafer 102. Thus, the “point” (intersection 156) that the apparatus is evaluating the location of is a virtual point. However, the position of that virtual point relative to the edge of the wafer in planes that are co-planar with the rotational axis will generally be the same about the circumference of the semiconductor wafer and may thus still be used to evaluate centeredness of the semiconductor wafer 102 on the rotational axis as well as the amount of elevational variance in the wafer edge of the semiconductor wafer 102 about the circumference of the semiconductor wafer 102.

In the depicted example of FIG. 4, the transition between the occluded portion 152a and the un-occluded portion 154a of the first light 116 occurs at a distance X′ along the first axis 148b of the second frame of reference 146b from the origin of the second frame of reference 146b, and the transition between the occluded portion 152b and the un-occluded portion 154b of the second light 118 occurs at a distance Z′ along the second axis 150b of the second frame of reference 146b from the origin of the second frame of reference 146b. The location of the intersection 156 may thus be expressed as coordinates (X′, Z′) relative to the second frame of reference 146b.

Since the orientation (angle θ) of the second frame of reference 146b to the first frame of reference 146a is known, it is relatively trivial to transform the coordinates (X′, Z′) into coordinates (X, Z) in the first frame of reference 146a as shown in FIG. 5. For example, using rotational transform equations:

$$X = {X}^{′} cos ( θ ) + {Z}^{′} sin ( θ )$$

$$Z = - {X}^{′} sin ( θ ) + {Z}^{′} cos ( θ )$$

It will be understood that a similar approach may be used in implementations in which the first direction 130 and the second direction 132 are not orthogonal to one another, but at oblique angles to one another instead. Such implementations may be used when it is desirable to skew the accuracy of the measurements made to be greater along the first axis 148a or the second axis 150a of the first frame of reference 146a than the other of the first axis 148a or the second axis 150a of the first frame of reference 146a.

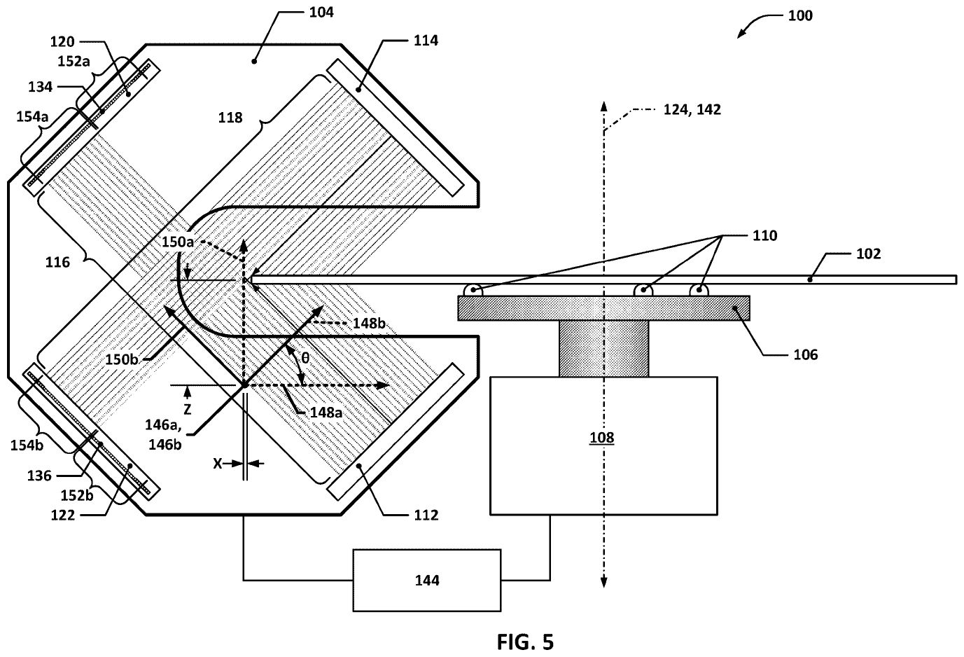

For example, if accuracy of the offset of the wafer center from the rotational axis is more important than accuracy of the elevational changes of the wafer edge about the circumference of a semiconductor wafer, then an implementation similar to that shown in FIG. 6 may be used, in which the first light emitted by a first light source 612 and second light emitted by a second light source 614 may be emitted along directions that are at angles of less than 45° from axes parallel to a rotational axis 624 of a wafer support 606. The closer that the first direction and the second direction are to rotational axis 624, the more the accuracy of the measurement along the first axis of the first frame of reference will be and the lower the accuracy of the measurement along the second axis of the first frame of reference will be.

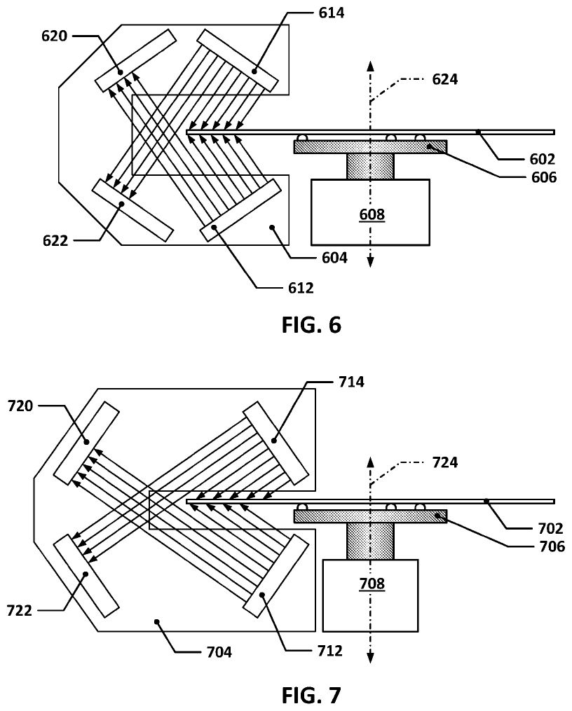

Similarly, if accuracy of the elevational changes of the wafer edge about the circumference of a semiconductor wafer is more important than accuracy of the offset of the wafer center from the rotational axis, then an implementation similar to that shown in FIG. 7 may be used, in which the first light emitted by a first light source 712 and second light emitted by a second light source 714 may be emitted along directions that are at angles of more than 45° from axes parallel to a rotational axis 724 of a wafer support 706.

It will be understood that other elements in FIGS. 6 and 7 are not specifically discussed above, but are similar to elements in FIG. 1 that have callouts with the same last two digits, and that the prior discussion of such elements is equally applicable to the elements in FIGS. 6 and 7 having the same last two digits in the drawing callouts.

In implementations such as those depicted in FIG. 6 or 7, e.g., in which the first direction and the second direction are not orthogonal, the first direction and the second direction may not necessarily define a frame of reference with orthogonal axes. In such implementations, it may be necessary to transform the measurements taken by one or both light detectors into coordinates in the second frame of reference prior to transforming the coordinates in the second frame of reference into coordinates in the first frame of reference.

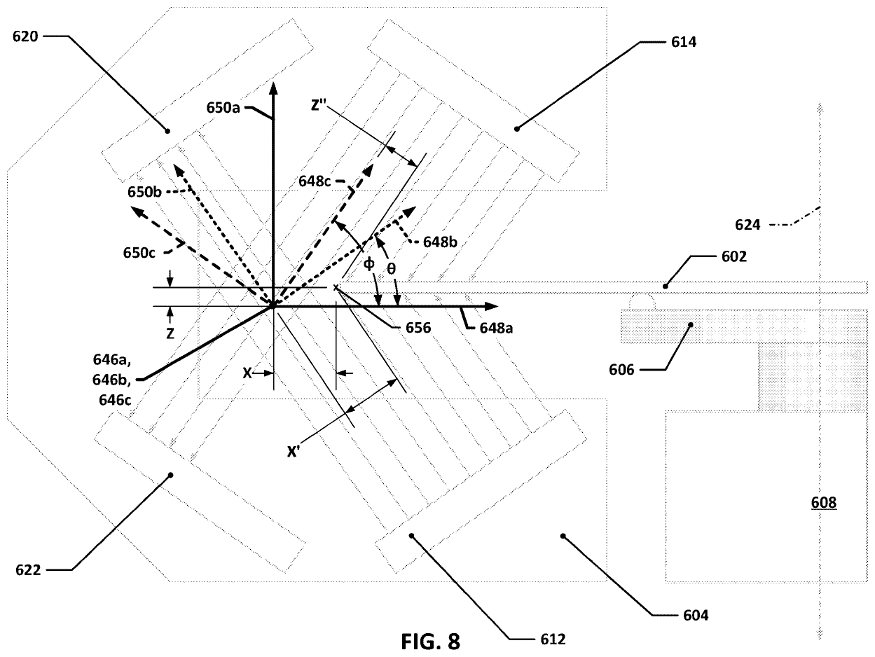

FIG. 8 depicts FIG. 6, but with three frames of reference indicated as well. The elements of FIG. 8 are the same as FIG. 6 except for these additional frames of reference, and the reader is referred to the earlier discussion of FIG. 6 for discussion of the elements common to both Figures. To reduce visual clutter, the elements of FIG. 6 shown in FIG. 8 are rendered in light gray line coloring. FIG. 8, as stated above, includes a first frame of reference 646a, a second frame of reference 646b, and a third frame of reference 646c. The first frame of reference 646a is shown in solid lines and is aligned with the vertical and horizontal directions, with a first axis 648a extending horizontally and a second axis 650a extending vertically. The second frame of reference 646b is shown in dotted lines and has a first axis 648b, a second axis 650b that is perpendicular to the first axis 648b, and is oriented such that the first axis 648b is aligned with the direction along which the first light source 612 and the first light detector 620 measure where the edge of the wafer 602 is located. The third frame of reference 646c is shown in dashed lines and similarly has a first axis 648c, a second axis 650c that is perpendicular to the first axis 648c, and is oriented such that the second axis 650c is aligned with the direction along which the second light source 614 and the second light detector 622 measure where the edge of the wafer 602 (or, more accurately, the virtual edge/intersection point 656) is located. The angles θ and φ indicate the angular offsets between the first axis 648a and the first axes 648b and 648c, respectively.

In such a system, the distance measurements obtained by the first light source 612/first light detector 620 along the first axis 648b (indicated by X′) and the second light source 614/second light detector 622 along the second axis 650c (indicated by Z″) may be converted into coordinates in the first frame of reference 646a using the transforms:

$$X = \frac{{X}^{′} cos ∅ - {Z}^{″} sin θ}{cos ∅ cos θ + sin ∅ sin θ}$$

$$Z = \frac{{Z}^{″} cos θ + {X}^{′} sin ∅}{cos ∅ cos θ + sin ∅ sin θ}$$

Such a transform may also be used, for example, to obtain coordinates in the first frame of reference for a system such as that shown in FIG. 7 (or any system in which the first direction and the second direction are not orthogonal to one another).

The first frame of reference and the second frame of reference may be chosen as desired for a given apparatus, although if absolute measurements of the position of the wafer edge relative to the rotational axis and/or a fixed horizontal reference plane are desired, it will be necessary to established where the first frame of reference and the second frame of reference are, e.g., by performing a calibration procedure in which a wafer that is flat and centered on the rotational axis is measured with the apparatus and then used to establish a baseline measurement that is then used to correct measurements taken during normal use.

Generally speaking, for evaluating wafer off-centeredness and wafer edge vertical variance, it is usually sufficient to simply rotate the semiconductor wafer through a number of rotational positions and take a measurement at each such position and then transform it into coordinates in the first frame of reference. Since the first frame of reference for each such measurement will be the same, the changes in X and Z across the population of such measurements will be representative of the amount of off-centeredness and/or vertical variance about the circumference of the wafer edge.

Wafer off-centeredness refers to how much the center of the wafer is off-center from the rotational axis of the wafer support. Such off-centeredness determinations may then be used to adjust how a wafer-handling robot subsequently positions its end effector when preparing to pick up the wafer from the wafer support using the end effector, e.g., the wafer-handling robot can position the end effector with an offset from a default position relative to the center axis to compensate for a similar offset in the wafer from the center axis, thereby causing the wafer to be positioned in a desired position relative to the end effector after the end effector is used to pick the wafer up.

Wafer edge vertical variance refers to how much deviation there is in the distance from the edge of the wafer to a plane that is perpendicular to the rotational axis of the wafer support. For example, a wafer that is not warped at all (i.e., that is perfectly flat) will, when supported on the wafer support, have an edge that is the exactly the same distance from such a plane about the entire wafer circumference (this assumes that the wafer support positions the wafer such that it is parallel to such a plane, of course). However, a wafer that is bowed or otherwise warped will have a wafer edge that varies in distance from such a plane about the circumference of the wafer. The greater the variance in this distance, the greater the amount of warpage or non-planarity. Measurements of such variance may thus provide insight as to the amount of warpage experienced by a wafer. For example, in some implementations, the controller may be configured to cause a semiconductor wafer placed on the wafer support to rotate through N rotational positions and take a measurement in the second frame of reference at each such rotational position of the virtual point defined by the wafer edge that is then transformed into the first frame of reference. In some such implementations, such a set of measurements may be taken at evenly spaced intervals about the circumference of the semiconductor wafer, e.g., every degree or every five degrees, for a full rotation of the semiconductor wafer. In instances in which N measurements are to be obtained about the circumference of the semiconductor wafer, the controller may be configured to cause the wafer support to rotate by at least 360° minus 360°/N during the collection of such a set of N measurements, which is the minimum amount of rotation needed to allow for N such measurements to be obtained at evenly spaced locations about the entire circumference of the semiconductor wafer.

In such implementations, the controller may be further configured to evaluate the collected measurements to identify maximum and minimum values of X and/or Z for the semiconductor wafer being measured. Such parameters may then be reported out to a user or used to drive the configuration of other pieces of equipment, e.g., a semiconductor processing tool or wafer-handling robot may be provided with such parameters or other parameters derived from such measurements, or with the measurements themselves, in order to allow the semiconductor processing tool or wafer-handling robot to configure itself in a manner that may compensate for or correct for off-centeredness of the semiconductor wafer from the rotational axis of the wafer support and/or variance in the elevational profile of the wafer edge.

The control of a measurement apparatus as discussed herein, as well as potentially other equipment discussed above (such as wafer handling robots, semiconductor processing tools, etc.) may be facilitated through the use of a controller that may be included as part of such an apparatus or as part of a semiconductor processing tool. The systems discussed above may be integrated with electronics for controlling their operation during measurement of a semiconductor wafer or substrate. The electronics may be referred to as the “controller,” which may control various components or subparts of the system or systems.

Broadly speaking, the controller may be defined as electronics having various integrated circuits, logic, memory, and/or software that receive instructions, issue instructions, control operation, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular measurement or evaluation process on or for a semiconductor wafer or to a system.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of apparatuses discussed herein. The computer may enable remote access to the system to monitor current progress of measurement operations, examine a history of past measurement operations, examine trends or performance metrics from a plurality of measurement operations for different semiconductor wafers, to change parameters of current measurements, to set steps to follow a current measurement, or to start a new process. In some examples, a remote computer (e.g. a server) can provide process measurement instructions to an apparatus as discussed herein over a network, which may include a local network or the Internet. The remote computer may include a user interface that enables entry or programming of parameters and/or settings, which are then communicated to the measurement apparatus from the remote computer. In some examples, the controller receives instructions in the form of data, which specify parameters for each of the measurement steps to be performed by such an apparatus. It should be understood that the parameters may be specific to the type of measurement to be performed and the type of measurement apparatus that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a measurement apparatus in communication with one or more integrated circuits located remotely (such as at the platform level or as part of a remote computer) that combine to control a measurement process using such an apparatus.

Without limitation, the measurement apparatuses discussed herein may be used in isolation or as part of example systems that may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the measurement step or steps to be performed by the apparatus, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. However, it will also be understood that the above disclosure is directed to at least the following non-exclusive implementations:

Implementation 1: An apparatus including a support structure, a first light source supported by the support structure and configured to emit first light along a first direction that is at an oblique angle to a first reference axis, the first reference axis being parallel to a vertical axis associated with the support structure, a second light source supported by the support structure and configured to emit second light along a second direction that is at an oblique or perpendicular angle to the first direction and that is at an oblique angle to a second reference axis, the second reference axis being parallel to the vertical axis associated with the support structure, a first light detector supported by the support structure and configured so as to detect at least a portion of the first light emitted by the first light source, and a second light detector supported by the support structure and configured so as to detect at least a portion of the second light emitted by the second light source.

Implementation 2: The apparatus of implementation 1, in which the first direction is orthogonal to the second direction.

Implementation 3: The apparatus of implementation 1 or implementation 2, in which the first direction is at a 45° angle to the first reference axis.

Implementation 4: The apparatus of implementation 1, in which the first direction is at an oblique angle to the second direction.

Implementation 5: The apparatus of any one of implementations 1 through 4, in which the first light is a first collimated planar beam of light that is coplanar with the first reference axis, and the second light is a second collimated planar beam of light that is coplanar with the second reference axis.

Implementation 6: The apparatus of implementation 4, in which the vertical axis associated with the support structure is coplanar with the first collimated planar beam of light and the second collimated planar beam of light.

Implementation 7: The apparatus of any one of implementations 1 through 6, in which the first light source includes a first linear array of first light-emitting devices arranged along a first array axis, the second light source includes a second linear array of second light-emitting devices arranged along a second array axis, the first array axis is perpendicular to the first direction, and the second array axis is perpendicular to the second direction.

Implementation 8: The apparatus of implementation 7, in which the first array axis and the second array axis each lie in planes that are parallel to or coplanar with one another.

Implementation 9: The apparatus of any one of implementations 1 through 6, in which the first light detector includes a first linear charge-coupled device (L-CCD) having a corresponding first photo-sensitive surface that is orthogonal to the first direction, and the second light detector includes a second L-CCD having a corresponding second photo-sensitive surface that is orthogonal to the second direction.

Implementation 10: The apparatus of any one of implementations 1 through 9, in which the first light source and the second light source are both positioned so as to direct a portion of the first light and a portion of the second light, respectively, through a first point.

Implementation 11: The apparatus of any one of implementations 1 through 10, in which the support structure does not extend into a region that has a center axis that is coaxial with the vertical axis associated with the support structure, the center axis extends into a space between the first light source and the first light detector and into another space between the second light source and the second light detector.

Implementation 12: The apparatus of any one of implementations 1 through 11, further including a wafer support that is configured to rotate about a rotational axis.

Implementation 13: The apparatus of implementation 12, further including a controller, in which the controller is configured to a) obtain measurements in a first frame of reference that is not aligned with the vertical axis associated with the support structure using the first light source, the second light source, the first light detector, and the second light detector, each measurement indicating an amount of the first light and the second light emitted by the first light source and the second light source, respectively, that is detected by the first light detector and the second light detector, respectively, b) determine a position of an object in the first frame of reference based on the measurements, and c) convert the position of the object in the first frame of reference into an equivalent position in a second frame of reference, in which the second frame of reference has a first axis that is parallel to the vertical axis associated with the support structure and a second axis that is perpendicular to the first axis.

Implementation 14: The apparatus of implementation 13, in which the controller is further configured to d) cause the rotatable wafer support to rotate about the rotational axis and through a plurality of different rotational positions for a first set of measurements associated with the object; and e) repeat (a) through (c) for each rotational position.

Implementation 15: The apparatus of implementation 14, in which the controller is configured to, as part of (d), cause the rotatable wafer support to move through N rotational positions and to rotate by the same amount when rotating between each set of adjacent rotational positions, and the controller is configured to, also as part of (d), cause the rotatable wafer support to rotate at least 360° minus 360°/N.

Implementation 16: The apparatus of implementation 14 or implementation 15, in which the controller is further configured to determine a maximum displacement of the position along the first axis across the plurality of different rotational positions indicated by the first set of measurements for the object.

Implementation 17: The apparatus of any one of implementations 14 through 16, in which the controller is further configured to determine a maximum displacement of the position along the second axis across the plurality of different rotational positions indicated by the first set of measurements for the object.

Implementation 18: The apparatus of any one of implementations 14 through 17, wherein the object is a semiconductor wafer.

1. An apparatus comprising:
a support structure;
a first light source supported by the support structure and configured to emit first light along a first direction that is at an oblique angle to a first reference axis, the first reference axis being parallel to a vertical axis associated with the support structure;
a second light source supported by the support structure and configured to emit second light along a second direction that is at an oblique or perpendicular angle to the first direction and that is at an oblique angle to a second reference axis, the second reference axis being parallel to the vertical axis associated with the support structure;
a first light detector supported by the support structure and configured so as to detect at least a portion of the first light emitted by the first light source; and
a second light detector supported by the support structure and configured so as to detect at least a portion of the second light emitted by the second light source.

2. The apparatus of claim 1, wherein the first direction is orthogonal to the second direction.

3. The apparatus of claim 1, wherein the first direction is at a 45° angle to the first reference axis.

4. The apparatus of claim 1, wherein the first direction is at an oblique angle to the second direction.

5. The apparatus of claim 1, wherein:
the first light is a first collimated planar beam of light that is coplanar with the first reference axis, and
the second light is a second collimated planar beam of light that is coplanar with the second reference axis.

6. The apparatus of claim 5, wherein the vertical axis associated with the support structure is coplanar with the first collimated planar beam of light and the second collimated planar beam of light.

7. The apparatus of claim 1, wherein:
the first light source includes a first linear array of first light-emitting devices arranged along a first array axis,
the second light source includes a second linear array of second light-emitting devices arranged along a second array axis,
the first array axis is perpendicular to the first direction, and
the second array axis is perpendicular to the second direction.

8. The apparatus of claim 7, wherein the first array axis and the second array axis each lie in planes that are parallel to or coplanar with one another.

9. The apparatus of claim 1, wherein:
the first light detector includes a first linear charge-coupled device (L-CCD) having a corresponding first photo-sensitive surface that is orthogonal to the first direction, and
the second light detector includes a second L-CCD having a corresponding second photo-sensitive surface that is orthogonal to the second direction.

10. The apparatus of claim 1, wherein the first light source and the second light source are both positioned so as to direct a portion of the first light and a portion of the second light, respectively, through a first point.

11. The apparatus of claim 1, wherein the support structure does not extend into a region that has a center axis that is coaxial with the vertical axis associated with the support structure, the center axis extends into a space between the first light source and the first light detector and into another space between the second light source and the second light detector.

12. The apparatus of claim 1, further comprising a rotatable wafer support that is configured to rotate about a rotational axis.

13. The apparatus of claim 12, further comprising a controller, wherein the controller is configured to:
a) obtain measurements in a first frame of reference that is not aligned with the vertical axis associated with the support structure using the first light source, the second light source, the first light detector, and the second light detector, each measurement indicating an amount of the first light and the second light emitted by the first light source and the second light source, respectively, that is detected by the first light detector and the second light detector, respectively;
b) determine a position of an object in the first frame of reference based on the measurements; and
c) convert the position of the object in the first frame of reference into an equivalent position in a second frame of reference, wherein the second frame of reference has a first axis that is parallel to the vertical axis associated with the support structure and a second axis that is perpendicular to the first axis.

14. The apparatus of claim 13, wherein the controller is further configured to:
d) cause the rotatable wafer support to rotate about the rotational axis and through a plurality of different rotational positions for a first set of measurements associated with the object; and
e) repeat (a) through (c) for each rotational position.

15. The apparatus of claim 14, wherein:
the controller is configured to, as part of (d), cause the rotatable wafer support to move through N rotational positions and to rotate by the same amount when rotating between each set of adjacent rotational positions, and
the controller is configured to, also as part of (d), cause the rotatable wafer support to rotate at least 360° minus 360°/N.

16. The apparatus of claim 14, wherein the controller is further configured to determine a maximum displacement of the position along the first axis across the plurality of different rotational positions indicated by the first set of measurements for the object.

17. The apparatus of claim 14, wherein the controller is further configured to determine a maximum displacement of the position along the second axis across the plurality of different rotational positions indicated by the first set of measurements for the object.

18. The apparatus of claim 14, wherein the object is a semiconductor wafer.

19. The apparatus of claim 15, wherein the controller is further configured to determine a maximum displacement of the position along the second axis across the plurality of different rotational positions indicated by the first set of measurements for the object.

20. The apparatus of claim 16, wherein the controller is further configured to determine a maximum displacement of the position along the second axis across the plurality of different rotational positions indicated by the first set of measurements for the object.
